(19) United States
(12) Patent Application Publication
(10) Pub. No.: US 2025/0107158 A1
(43) Pub. Date: Mar. 27, 2025

(54) THIN FILM TRANSISTOR SUBSTRATE AND DISPLAY DEVICE USING THE SAME

(71) Applicant: LG Display Co., Ltd., Seoul (KR)

(72) Inventor: JaeHyun KIM, Paju-si (KR)

(73) Assignee: LG Display Co., Ltd., Seoul (KR)

(21) Appl. No.: 18/894,155

(22) Filed: Sep. 24, 2024

(30) Foreign Application Priority Data
Sep. 25, 2023 (KR) 10-2023-0128053

(51) Int. Cl. H01L 29/786; H01L 29/417; H01L 29/423

(52) U.S. Cl. CPC H10D 30/6757; H10D 30/6729; H10D 30/673

(57) ABSTRACT

A thin film transistor substrate may include a substrate, an active layer disposed on the substrate, a gate electrode disposed on the active layer, a source electrode connected to one side of the active layer, and a drain electrode connected to another side of the active layer. The gate electrode may include a first side convexly disposed in a direction of any one of the source electrode and the drain electrode, the active layer may include a plurality of first active holes overlapping the first side, and the plurality of first active holes may be arranged in a direction perpendicular to a direction in which the source electrode and the drain electrode face each other. A display device using the thin film transistor substrate is also disclosed.

### CROSS-REFERENCE TO RELATED APPLICATIONS

This application claims the benefit of and priority to Korean Patent Application No. 10-2023-0128053 filed on Sep. 25, 2023, the entire contents of which are incorporated herein by reference for all purposes, as if fully set forth herein.

### BACKGROUND

### 1. Technical Field

The present disclosure relates to a thin film transistor substrate and a display device using the same.

### 2. Description of the Related Art

Since thin film transistors can be manufactured on glass or plastic substrates, they are widely used as switching or driving elements of display devices such as liquid crystal display devices or organic light emitting devices.

Various types of thin film transistors such as a display area thin film transistor that emits individual pixels, a Logic-GIP thin film transistor for controlling the display area thin film transistor, and a Buffer-GIP thin film transistor that controls the overall power supply may be used for the display panel for driving the organic light emitting device (OLED).

In order to implement a device having high mobility, in a thin film transistor having a top gate structure, a process of conducting an oxide semiconductor layer may be performed by using a gate electrode as a mask. However, in the process of conducting the oxide semiconductor layer, a region to be conductive may be excessively penetrated, and thus the channel region may be formed to be smaller than the set region, and accordingly, the channel length may be reduced and the threshold voltage Vth may be shifted in the negative (−) direction. In particular, when the width of the oxide semiconductor layer is large, the degree of penetration of the region to be conductive may increase, and thus the channel length may be further shortened.

When the threshold voltage Vth is shifted in the negative (−) direction, a leakage current may occur in an initial image. As a result, a display panel including a thin film transistor may be driven poorly due to the leakage current, and a problem in which power consumption of the panel increases may occur.

The description of the related art should not be assumed to be prior art merely because it is mentioned in or associated with this section. The description of the related art includes information that describes one or more aspects of the subject technology, and the description in this section does not limit the invention.

### SUMMARY

The present disclosure has been made in view of the problems and needs of the related art as well as the above problems, and one or more aspects of the present disclosure provide a thin film transistor substrate on which the channel part of the active layer can secure the same effective channel length in the width direction since the gate electrode includes one side which is convex in a direction of any one of the source electrode and the drain electrode, with certain curvature, and the display device including the same.

One or more aspects of the present disclosure can be accomplished by the provision of a thin film transistor substrate and a display device including the same. In one or more examples, the thin film transistor substrate comprises a substrate, an active layer disposed on the substrate, a gate electrode disposed on the active layer, a source electrode connected to one side of the active layer, and a drain electrode connected to another side of the active layer, wherein the gate electrode includes a first side convexly disposed in a direction of any one of the source electrode and the drain electrode, the active layer includes a plurality of first active holes overlapping the first side, and the plurality of first active holes are arranged in a direction perpendicular to a direction in which the source electrode and the drain electrode face each other.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure.

FIG. 1A is a plan view of a thin film transistor substrate according to an example embodiment of the present disclosure.

FIG. 1B is a plan view showing an active layer of a thin film transistor substrate according to an example embodiment of the present disclosure.

FIG. 2A is a cross-sectional view of a thin film transistor substrate according to an example embodiment of the present disclosure. In this case, the cross-sectional view of FIG. 2A corresponds to the cross-section taken along the line I-I′ of FIG. 1A.

FIG. 2B is a cross-sectional view of a thin film transistor substrate according to an example embodiment of the present disclosure. In this case, the cross-sectional view of FIG. 2B corresponds to the cross-section taken along the line II-II′ of FIG. 1A.

FIG. 3 is a plan view of a thin film transistor substrate according to another embodiment of the present disclosure.

FIG. 4A is a cross-sectional view of a thin film transistor substrate according to an example embodiment of the present disclosure. In this case, the cross-sectional view of FIG. 4A corresponds to the cross-section taken along the line III-III′ of FIG. 3.

FIG. 4B is a cross-sectional view of a thin film transistor substrate according to an example embodiment of the present disclosure. In this case, the cross-sectional view of FIG. 4B corresponds to the cross-section taken along the line IV-IV′ of FIG. 3.

FIG. 5A is a graph showing the length Leff of a channel part according to a position of a thin film transistor substrate according to a comparative example, and FIG. 5B is a graph showing the length Leff of a channel part according to a position of a thin film transistor substrate according to another embodiment of the present disclosure.

FIG. 6 is a plan view of a thin film transistor substrate according to another embodiment of the present disclosure.

FIG. 7 is a plan view of a thin film transistor substrate according to another embodiment of the present disclosure.

FIG. 8 is a plan view of a thin film transistor substrate according to another embodiment of the present disclosure.

FIG. 9A is a cross-sectional view of a thin film transistor substrate according to another embodiment of the present disclosure. In this case, the cross-sectional view of FIG. 9A corresponds to the cross-section taken along the line V-V′ of FIG. 8.

FIG. 9B is a cross-sectional view of a thin film transistor substrate according to another embodiment of the present disclosure. In this case, the cross-sectional view of FIG. 9B corresponds to the cross-section taken along the line VI-VI′ of FIG. 8.

FIG. 10 is a cross-sectional view of a thin film transistor substrate according to another embodiment of the present disclosure. In this case, the cross-sectional view of FIG. 10 corresponds to the cross-section taken along the line V-V′ of FIG. 8.

FIG. 11 is a cross-sectional view of a display device including a thin film transistor substrate according to an example embodiment of the present disclosure.

FIG. 12 is a schematic view of a display device according to an example embodiment of the present disclosure.

FIG. 13 is a circuit diagram of a pixel included in a display device according to an example embodiment of the present disclosure.

FIG. 14 is a circuit diagram of a pixel included in a display device according to another embodiment of the present disclosure.

FIG. 15 is a circuit diagram of a pixel included in a display device according to another embodiment of the present disclosure.

FIG. 16 is a schematic diagram of a shift register according to an example embodiment of the present disclosure.

FIG. 17 is a circuit diagram of a shift register according to an example embodiment of the present disclosure.

Throughout the drawings and the detailed description, unless otherwise described, the same drawing reference numerals should be understood to refer to the same elements, features, and structures. The sizes, lengths, and thicknesses of layers, regions and elements, and depiction thereof may be exaggerated for clarity, illustration, and/or convenience.

### DETAILED DESCRIPTION

Advantages and features of the present disclosure, and implementation methods thereof will be clarified through the following embodiments, described with reference to the accompanying drawings. The present disclosure may, however, be embodied in different forms and should not be construed as being limited to the embodiments set forth herein. Rather, these embodiments are provided so that this disclosure will be thorough and complete, and will fully convey the scope of the present disclosure to those skilled in the art. Further, the present disclosure is only defined by the scope of the claims.

The shapes, sizes, ratios, angles, and numbers disclosed in the drawings for describing embodiments of the present disclosure are merely examples, and thus the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

In the case in which “comprise,” “have,” and “include” described in the present specification are used, another part may also be present unless “only” is used. The terms in a singular form may include plural forms unless noted to the contrary.

In construing an element, the element is construed as including an error region although there is no explicit description thereof.

In describing a positional relationship, for example, when the positional order is described as “on,” “above,” “below,” “beneath,” and “next,” the case of no contact therebetween may be included, unless “just” or “direct” is used.

If it is mentioned that a first element is positioned “on” a second element, it does not mean that the first element is essentially positioned above the second element in the figure. The upper part and the lower part of an object concerned may be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as “after,” “subsequent,” “next,” and “before,” a case which is not continuous may be included, unless “just” or “direct” is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element.

It should be understood that the term “at least one” includes all combinations related with any one item. For example, “at least one among a first element, a second element and a third element” may include all combinations of two or more elements selected from the first, second and third elements as well as each element of the first, second and third elements.

Features of various embodiments of the present disclosure may be partially or overall coupled to or combined with each other, and may be variously inter-operated with each other and driven technically The embodiments of the present disclosure may be carried out independently from each other, or may be carried out together in a co-dependent relationship.

In the drawings, the same or similar elements are denoted by the same reference numerals even though they are depicted in different drawings.

In the embodiments of the present disclosure, a source electrode and a drain electrode are distinguished from each other, for convenience of explanation. However, the source electrode and the drain electrode are used interchangeably. Thus, the source electrode may be the drain electrode, and the drain electrode may be the source electrode. Also, the source electrode in any one embodiment of the present disclosure may be the drain electrode in another embodiment of the present disclosure, and the drain electrode in any one embodiment of the present disclosure may be the source electrode in another embodiment of the present disclosure.

In one or more embodiments of the present disclosure, for convenience of explanation, a source region is distinguished from a source electrode, and a drain region is distinguished from a drain electrode. However, embodiments of the present disclosure are not limited to this structure. For example, a source region may be a source electrode, and a drain region may be a drain electrode. Also, a source region may be a drain electrode, and a drain region may be a source electrode.

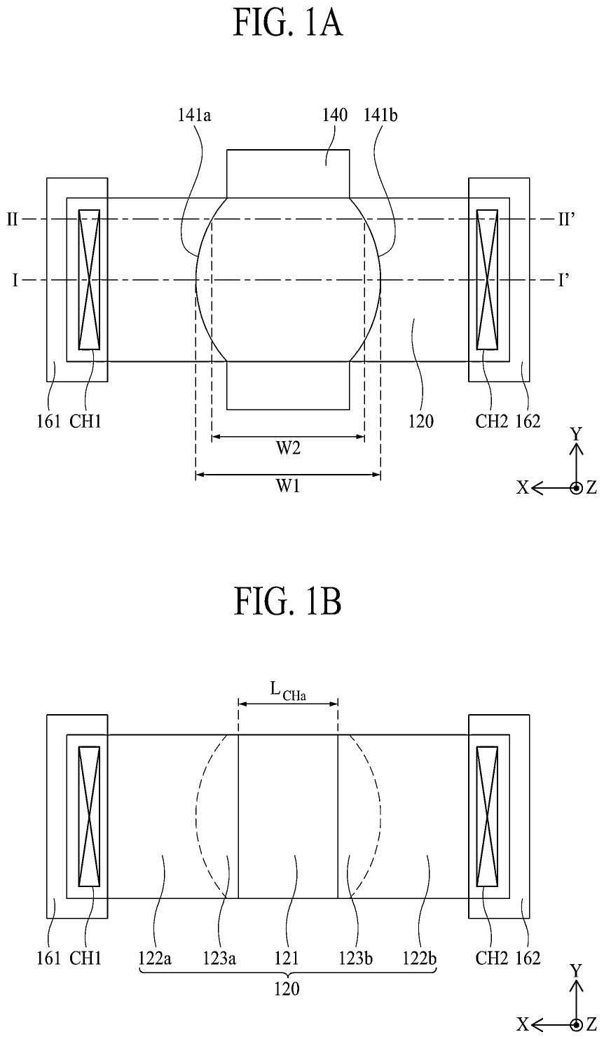

FIG. 1A is a plan view of a thin film transistor substrate according to an example embodiment of the present disclosure.

As shown in FIG. 1A, a thin film transistor substrate according to an example embodiment of the present disclosure may include an active layer 120, a gate electrode 140, a source electrode 161, and a drain electrode 162.

The active layer 120 may extend in a first direction X, for example, a horizontal direction. In this case, the first direction X may be defined as a direction in which the source electrode 161 and the drain electrode 162 face each other.

A first contact hole CH1 may be provided on one side of the active layer 120, for example, a left side, and a second contact hole CH2 may be provided on another side of the active layer 120, for example, a right side. In this case, one side of the active layer 120 may be electrically connected to the source electrode 161 through the first contact hole CH1, and another side of the active layer 120 may be electrically connected to the drain electrode 162 through the second contact hole CH2.

The gate electrode 140 may extend in a second direction Y, for example, a vertical direction. In this case, the second direction Y may be defined as a direction orthogonal to the first direction X.

According to an example embodiment of the present disclosure, the gate electrode 140 may have a convex shape. Specifically, the gate electrode 140 may be provided to be convex in the first direction X. For example, the gate electrode 140 may include a first side 141a convex in a direction of the source electrode 161 and a second side 141b convex in a direction of the drain electrode 162 while overlapping the active layer 120. In this case, the first side 141a and the second side 141b may be an arc having a constant curvature, but are not limited thereto.

Since the first side 141a of the gate electrode 140 is formed to be convex from the gate electrode 140, a distance between the first side 141a and the source electrode 161 may increase from the central portion of the active layer 120 to the edge portion of the active layer 120 along the second direction Y. Specifically, a distance between the first side 141a and the source electrode 161 may be the smallest at a central portion of the active layer 120, and a distance between the first side 141a and the source electrode 161 may be the greatest at a portion overlapping one side of the active layer 120, for example, an upper side. Likewise, a distance between the first side 141a and the source electrode 161 may be the greatest at a portion overlapping another side of the active layer 120, for example, the lower side.

Since the second side 141b of the gate electrode 140 is formed to be convex from the gate electrode 140, a distance between the second side 141b and the drain electrode 162 may increase from the central portion of the active layer 120 to the edge portion of the active layer 120 in the second direction Y. Specifically, a distance between the second side 141b and the drain electrode 162 may be the smallest in the central portion of the active layer 120, and a distance between the second side 141b and the drain electrode 162 may be the greatest at a portion overlapping one side of the active layer 120, for example, an upper side. Likewise, a distance between the second side 141b and the drain electrode 162 may be the greatest at a portion overlapping another side of the active layer 120, for example, a lower side.

According to an example embodiment of the present disclosure, the first side 141a and the second side 141b of the gate electrode 140 are formed to be convex in the direction of the source electrode 161 or the drain electrode 162, respectively, so that the gate electrode 140 may have different widths along the second direction Y. For example, the gate electrode 140 in the central portion of the active layer 120 may have a first width W1, and the gate electrode 140 may have a second width W2 in a region between the center portion of the active layer 120 and an upper side of the active layer 120. In this case, the first width W1 may be greater than the second width W2.

According to an example embodiment of the present disclosure, the gate electrode 140 includes the first side 141a and the second side 141b convexly provided in the direction of the source electrode 161 or the drain electrode 162, and thus, even if the conducting process is performed on the active layer 120 by using the gate electrode 140 as a mask, a problem in which the length of the channel part in the active layer 120 is formed shorter than that designed may be eliminated or minimized. Meanwhile, this will be described in more detail with reference to FIG. 1B, which will be described later.

FIG. 1B is a plan view showing an active layer of a thin film transistor substrate according to an example embodiment of the present disclosure. Meanwhile, FIG. 1B is a diagram excluding a gate electrode for convenience of describing an active layer of the thin film transistor substrate according to an embodiment of FIG. 1A. Since the configuration of the active layer is the same as that of an embodiment of FIG. 1A, repeated descriptions will be omitted below.

As shown in FIG. 1B, the active layer 120 may include a channel part 121, a first connection part 122a, a second connection part 122b, a first intermediate part 123a, and a second intermediate part 123b.

The active layer 120 may include the channel part 121, the first connection part 122a, the second connection part 122b, the first intermediate part 123a, and the second intermediate part 123b through a conducting process to give conductive properties to a partial region of the active layer 120 using the gate electrode (see 140 of FIG. 1A) as a mask.

The conducting process refers to a process of increasing an electron concentration in a partial region of the active layer 120 made of an oxide semiconductor, for example, a process of performing plasma treatment in the process of etching the gate insulating layer, or a process of doping dopant ions. When the conducting process is performed, an electron concentration increases in a partial region of the active layer 120 to have conductive characteristics, thereby having the same characteristics as a conductor. When the conducting process is performed as a process of doping dopant ions, the dopant ions may be boron B, phosphorus P, fluorine F, and hydrogen H.

According to an example embodiment of the present disclosure, a conducting process, for example, a process of doping dopant ions, may be performed using the gate electrode 140 as a mask. In this case, in the active layer 120, a region in which the dopant is not doped while overlapping the gate electrode 140, for example, the channel part 121 and a region in which the dopant is doped while not overlapping the gate electrode 140, for example the first connection part 122a and the second connection part 122b, and further, a region in which the dopant doped in the first connection part 122a or the second connection part 122b is diffused, while overlapping the gate electrode, for example, the first intermediate part 123a and the second intermediate part 123b may be formed. Meanwhile, the conducting process is not limited to the dopant doping process, but may include a conducting process by plasma treatment.

If the gate electrode does not have a convex first side and a second side and the width of the gate electrode is constant along the second direction Y, there may be a difference between a diffusion rate of dopant ions at a central portion of the active layer and a diffusion rate of dopant ions at an edge portion of the active layer.

Specifically, since the rate at which the dopant ions diffuse in the central portion of the active layer is faster than the rate at which the dopant ions diffuse in the edge portion of the active layer, the length of the channel part formed in the central portion of the active layer is formed to be shorter than the length of the channel part formed at the edge portion of the active layer. In other words, the channel part of the active layer may be formed to be concave in the direction of the source electrode or the drain electrode on the plan view. In this case, since the length of the channel part as designed may not be secured, the characteristics of the thin film transistor substrate may be formed to be different from those designed, and the length of the entire channel part may be shortened, resulting in a leakage current.”

According to one embodiment of the present disclosure, the gate electrode 140 is formed to be convex, and the first width W1 at the center of the active layer 120 is formed to be the largest, so that the amount of dopant ions excessively diffused into the channel part 121 during the conducting process in the center of the active layer 120 may be reduced.

The channel part 121 may have a first channel length L_{CHa} in the first direction X. According to an example embodiment of the present disclosure, since the gate electrode (see 140 of FIG. 1A) is convexly provided in a direction of the source electrode 161 or the drain electrode 162, even if the conducting process is performed on a partial region of the active layer 120 by using the gate electrode 140 as a mask, the channel part 121 may be formed to have the same first channel length L_{CHa} in the second direction Y without a separate curvature.

The first connection part 122a and the second connection part 122b may be formed on one side and another side of the channel part 121, respectively. Specifically, the first connection part 122a may be spaced apart from the channel part 121 with the first intermediate part 123a interposed therebetween. Likewise, the second connection part 122b may be spaced apart from the channel part 121 with the second intermediate part 123b interposed therebetween.

One side of the first connection part 122a may be electrically connected to the source electrode 161 through the first contact hole CH1, and another side of the second connection part 122b may be electrically connected to the drain electrode 162 through the second contact hole CH2.

The first intermediate part 123a and the second intermediate part 123b may be formed on one side and another side of the channel part 121, respectively. Specifically, the first intermediate part 123a may be provided on one side, for example, on the left side, of the channel part 121, and provided between the channel part 121 and the first connection part 122a, and the second intermediate part 123b may be provided on another side, for example, on the right side, of the channel part 121, and provided between the channel part 121 and the second connection part 122b.

The first intermediate part 123a and the second intermediate part 123b may be formed to be convex in the direction of the source electrode 161 or the drain electrode 162 along the gate electrode (see 140 of FIG. 1A).

According to an example embodiment of the present disclosure, the first intermediate part 123a and the second intermediate part 123b are covered by the gate electrode (see 140 of FIG. 1A), but some conductive characteristics are provided by dopant ions or plasma diffused from the first connection part 122a or the second connection part 122b, and a concentration of dopant ions diffused to the first intermediate part 123a and the second intermediate part 123b may be relatively lower than a concentration of dopant ions doped to the first connection part 122a and the second connection part 122b and may be relatively higher than a concentration of dopant ions of the channel part 121.

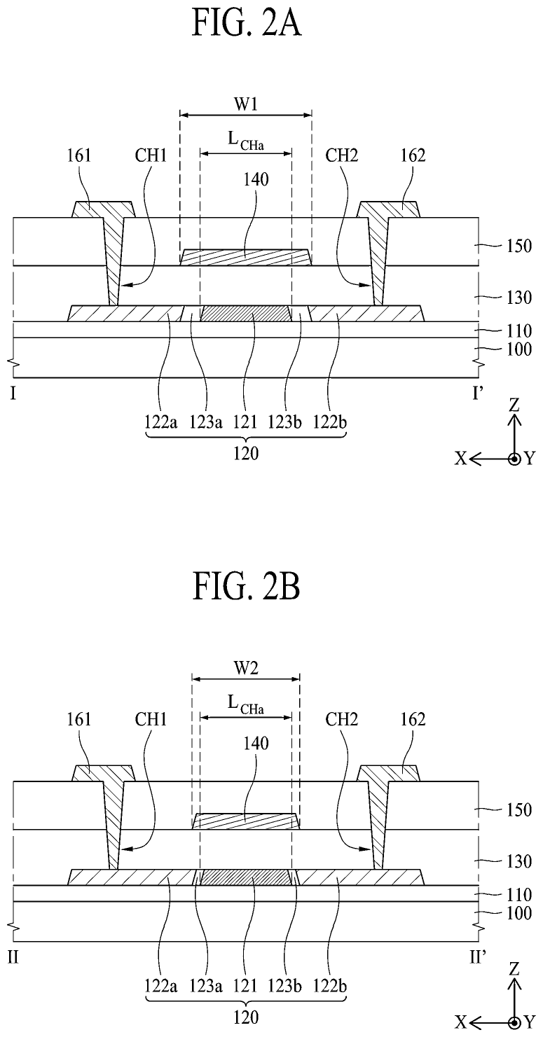

FIG. 2A is a cross-sectional view of a thin film transistor substrate according to an example embodiment of the present disclosure. In this case, the cross-sectional view of FIG. 2A corresponds to the cross-section taken along the line I-I′ of FIG. 1A.

As shown in FIG. 2A, a thin film transistor substrate according to an example embodiment of the present disclosure may include a substrate 100, a buffer layer 110, an active layer 120, a gate insulating layer 130, a gate electrode 140, an interlayer insulating layer 150, a source electrode 161, and a drain electrode 162.

The substrate 100 may be made of glass or plastic. In particular, the substrate 100 may be made of transparent plastic having flexible characteristics, for example, polyimide. When the polyimide is used as the substrate 100, considering that a high-temperature deposition process is performed on the substrate 100, heat-resistant polyimide capable of withstanding high temperature may be used.

The buffer layer 110 may be formed on the substrate 100. The buffer layer 110 may protect the active layer 120 by blocking air and moisture. The buffer layer 110 may be formed of an inorganic insulating material such as silicon oxide, silicon nitride, or metal oxide, but is not limited thereto and may be formed of an organic insulating material. The buffer layer 110 may be formed of a single layer, a plurality of layers, or may be omitted.

Meanwhile, although not shown in detail, a light blocking layer may be provided between the substrate 100 and the buffer layer 110. In this case, the light blocking layer may be provided in a larger area than the active layer 120 to prevent light introduced from the outside from moving to the active layer 120.

The active layer 120 may be provided on the buffer layer 110.

The active layer 120 may include a semiconductor material, for example, an oxide semiconductor material. The oxide semiconductor material may include at least one of, for example, an IZO (InZnO)-based oxide semiconductor material, an IGO (InGaO)-based oxide semiconductor material, an ITO (InSnO)-based oxide semiconductor material, an IGZO (InGaZnO)-based oxide semiconductor material, an IGZTO (InGaZnSnO)-based oxide semiconductor material, a GZTO (GaZnSnO)-based oxide semiconductor material, a GZO (GaZnO)-based oxide semiconductor material, an ITZO (InSnZnO)-based oxide semiconductor material, and a FIZO (FeInZnO)-based oxide semiconductor material.

The active layer 120 may include a channel part 121, a first connection part 122a, a second connection part 122b, a first intermediate part 123a, and a second intermediate part 123b.

The channel part 121 corresponds to a region in which the separate conducting process is no performed as the gate electrode 140 is overlapped, and thus semiconductor characteristics are maintained. In this case, the channel part 121 may have a first channel length L_{CHa} in the first direction X.

The first connection part 122a and the second connection part 122b may be provided on both sides of the channel part 121, respectively. Specifically, the first connection part 122a may be provided on one side, for example, on the left side, of the channel part 121, and the second connection part 122b may be provided on another side, for example, on the right side, of the channel part 121.

The first connection part 122a and the second connection part 122b may have conductive characteristics by a conducting process of performing ion doping or plasma treatment on a semiconductor material using the gate electrode 140 as a mask. Therefore, the first connection part 122a and the second connection part 122b may have better conductivity than the channel part 121, and each of them may serve as a wiring or source/drain electrode.

The first intermediate part 123a and the second intermediate part 123b may be provided between the channel part 121, the first connection part 122a, and the second connection part 122b, respectively. Specifically, the first intermediate part 123a may be provided between the channel part 121 and the first connection part 122a, and the second intermediate part 123b may be provided between the channel part 121 and the second connection part 122b.

Since the first intermediate part 123a and the second intermediate part 123b correspond to portions overlapping the gate electrode 140, one side of the first intermediate part 123a, for example, a left side, may be convexly provided in the direction of the source electrode 161 to have the same curvature as the first side 141a of the gate electrode 140, and one side of the second intermediate part 123b, for example, a right side, may be convexly provided in the direction of the drain electrode 162 to have the same curvature as the second side 141b of the gate electrode 140.

The first intermediate part 123a and the second intermediate part 123b overlap the gate electrode 140, but as the dopant ion or plasma doped into the first connection part 122a or the second connection part 122b is diffused during the conducting process, conductive characteristics may be provided to the first intermediate part 123a and the second intermediate part 123b by the diffused dopant ion or the diffused plasma. In this case, electrical conductivity of the first intermediate part 123a and the second intermediate part 123b may be lower than that of the first connection part 122a and the second connection part 122b.

According to an example embodiment of the present disclosure, one end of the first intermediate part 123a, for example, a left end may correspond to one end of the gate electrode 140, for example, a left end, and one end of the second intermediate part 123b, for example, a right end, may correspond to another end of the gate electrode 140, for example, a right end.

The gate insulating layer 130 may be provided on the active layer 120. In detail, the gate insulating layer 130 may be provided on the entire surface of the substrate 100, and may be provided on the active layer 120 and the buffer layer 110. As a result, the active layer 120 may be surrounded by the buffer layer 110 and the gate insulating layer 130.

The gate insulating layer 130 may include a silicon nitride layer SiNx or a silicon oxide layer SiOx, but is not limited thereto. The gate insulating layer 130 may be formed of a single layer or a plurality of layers including an inorganic insulating material and/or an organic insulating material. Meanwhile, although not illustrated, the gate insulating layer 130 is not limited to being provided on the entire surface of the substrate 100, and may be provided to coincide with one end and another end of the gate electrode 140.

The gate electrode 140 may be formed on the gate insulating layer 130.

The gate electrode 140 may have a first width W1 in the first direction X. In this case, the first width W1 may be greater than the first channel length L_{CHa} of the channel part 121.

The gate electrode 140 may include at least one of an aluminum-based metal such as aluminum Al or an aluminum alloy, a silver-based metal such as silver Ag or a silver alloy, a copper-based metal such as copper Cu or a copper alloy, a molybdenum-based metal such as molybdenum Mo or a molybdenum alloy, chromium Cr, tantalum Ta, neodymium Nd, and titanium Ti. The gate electrode 140 may have a structure including one metal layer or a multilayer structure including at least two metal layers each having different physical properties.

The interlayer insulating layer 150 insulates between the gate electrode 140 and the source electrode 161 and further insulates between the gate electrode 140 and the drain electrode 162. The interlayer insulating layer 150 may be formed of a single layer or a plurality of layers including an inorganic insulating material and/or an organic insulating material.

A first contact hole CH1 and a second contact hole CH2 may be provided in the interlayer insulating layer 150. Accordingly, a portion of the upper surface of the first connection part 122a of the active layer 120 may be exposed by the first contact hole CH1, and further, a portion of the upper surface of the second connection part 122b of the active layer 120 may be exposed by the second contact hole CH2.

The source electrode 161 and the drain electrode 162 may be disposed on the interlayer insulating layer 150.

The source electrode 161 may be electrically connected to the first connection part 122a of the active layer 120 by the first contact hole CH1, and the drain electrode 162 may be electrically connected to the second connection part 122b of the active layer 120 by the second contact hole CH2.

The source electrode 161 and the drain electrode 162 may be formed of the same material as the gate electrode 140, but are not limited thereto and may be formed of a material according to knowledge of the art.

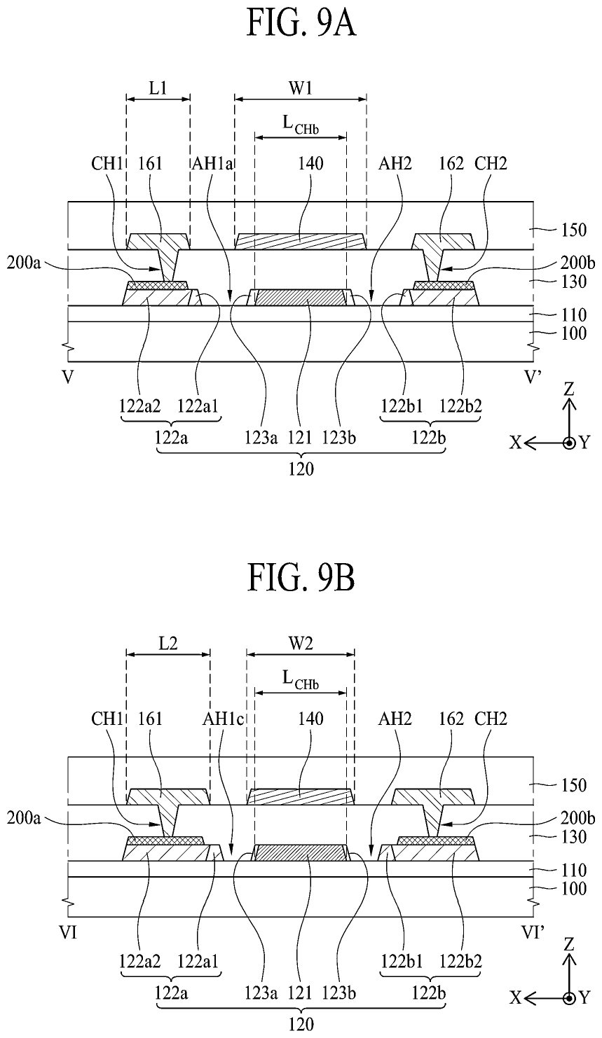

Meanwhile, although not shown in detail, the source electrode 161 and the drain electrode 162 may not be provided on the interlayer insulating layer 150, but may be formed on the same layer as the gate electrode 140 on the gate insulating layer 130. In this case, the gate electrode 140, the source electrode 161, and the drain electrode 162 may be patterned using the same material on the same layer and through the same process. Meanwhile, a form in which the gate electrode 140, the source electrode 161, and the drain electrode 162 are formed on the same layer will be described in more detail with reference to FIGS. 9A and 9B.

FIG. 2B is a cross-sectional view of a thin film transistor substrate according to an example embodiment of the present disclosure. In this case, the cross-sectional view of FIG. 2B corresponds to the cross-section taken along the line II-II′ of FIG. 1A. Meanwhile, an embodiment of FIG. 2B is the same as an embodiment of FIG. 2A except for an active layer and a gate electrode, and thus different configurations will be mainly described below.

As shown in FIG. 2B, according to an example embodiment of the present disclosure, the gate electrode 140 may be formed to have a second width W2 in the first direction X, and the second width W2 may be smaller than the first width W1 of the gate electrode 140 of FIG. 2A.

Meanwhile, although the second width W2 of the gate electrode 140 is formed to be smaller than the first width W1, the length of the channel part 121 may be the same as the length of the channel part 121 at the central portion. That is, the channel part 121 may have the first channel length L_{CHa}.

Furthermore, unlike FIG. 2A, lengths of the first intermediate part 123a and the second intermediate part 123b may also be formed to be narrower than those of FIG. 2A. For example, lengths of the first intermediate part 123a and the second intermediate part 123b in FIG. 2B in the first direction X may be shorter than lengths of the first intermediate part 123a and the second intermediate part 123b in FIG. 2A.

The second width W2 of the gate electrode 140 may be formed to be narrower than the first width W1 of the gate electrode 140 in FIG. 2A.

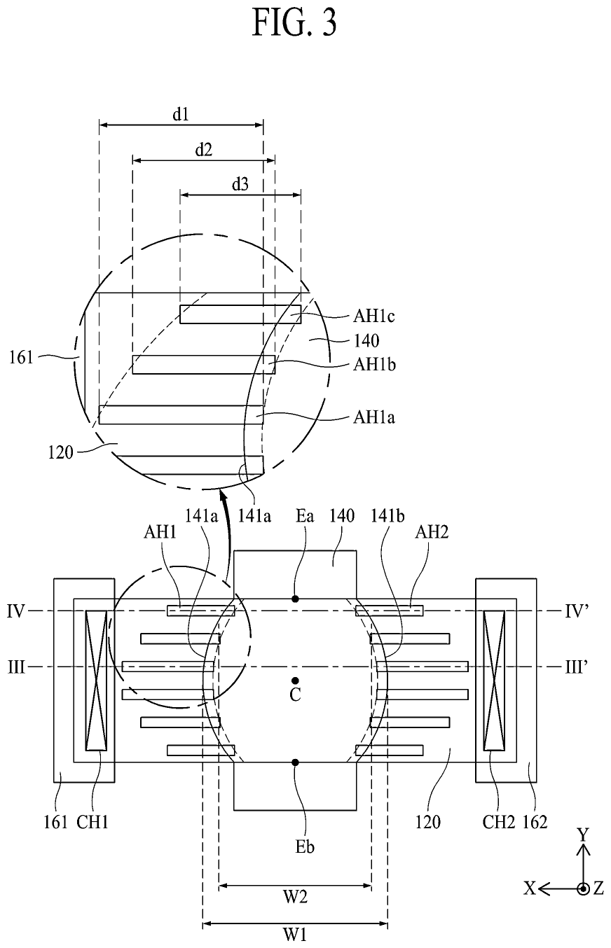

FIG. 3 is a plan view of a thin film transistor substrate according to another embodiment of the present disclosure. Meanwhile, an embodiment of FIG. 3 is the same as an embodiment of FIG. 1A except for a configuration of an active hole provided in an active layer, and thus different configurations will be mainly described below.

As shown in FIG. 3, a thin film transistor substrate according to another embodiment of the present disclosure may include an active layer 120, a gate electrode 140, a source electrode 161, and a drain electrode 162, and in this case, the active layer 120 may include a plurality of first active holes AH1 provided to be adjacent to the source electrode 161 and a plurality of second active holes AH2 provided to be adjacent to the drain electrode 162.

The plurality of first active holes AH1 and the plurality of second active holes AH2 may overlap the gate electrode 140. Specifically, the plurality of first active holes AH1 may be arranged in the second direction Y while overlapping the first side 141a of the gate electrode 140, and the plurality of second active holes AH2 may be arranged in the second direction Y while overlapping the second side 141b of the gate electrode 140.

One end of each of the plurality of first active holes AH1 may overlap the gate electrode 140, and another end of each of the plurality of first active holes AH1 may be provided to be adjacent to the source electrode 161 without overlapping the gate electrode 140, and one end of each of the plurality of second active holes AH2, for example, a left end, may overlap the gate electrode 140, and another end of each of the plurality of second active holes AH2 may be provided to be adjacent to the drain electrode 162 without overlapping the gate electrode 140.

According to another embodiment of the present disclosure, the plurality of first active holes AH1 and the plurality of second active holes AH2 may be formed along the first side 141a and the second side 141b of the gate electrode 140. For example, the plurality of first active holes AH1 may be formed along the first side 141a of the gate electrode 140, and the plurality of second active holes AH2 may be formed along the second side 141b of the gate electrode 140.

As shown in the enlarged view of FIG. 3, the plurality of first active holes AH1 may include, for example, a first hole AH1a provided adjacent to a central portion of the active layer 120, a third hole AH1c provided adjacent to an edge portion of the active layer 120, and a second hole AH1b provided between the first hole AH1a and the third hole AH1c.

In this case, one end of the first hole AH1a, for example, a right end overlapping with the gate electrode 140, one end of the second active hole AH2a, for example a right end overlapping with the gate electrode 140, and one end of the third active hole AH3a, for example a right end overlapping with the gate electrode 140, may be spaced apart from the first side 141a of the gate electrode 140 by the same distance. By forming in this way, the virtual curve connecting the centers of the first hole AH1a to the third hole AH1c may have the same curvature as the first side 141a of the gate electrode 140. Meanwhile, in FIG. 3, only the case in which the virtual curve connecting the centers of one ends of the plurality of first active holes AH1 has the same curvature as the first side 141a is illustrated, but the present disclosure is not limited thereto, and the virtual curve connecting the centers of one ends of the plurality of first active holes AH1 may have a curvature different from that of the first side 141a.

According to another embodiment of the present disclosure, the length of a portion where each of the plurality of first active holes AH1 overlaps the gate electrode 140 may be 0.1 m or more and 1.5 μm or less. Specifically, the minimum length from the centers of one end of the plurality of first active holes AH1 to the first side 141a of the gate electrode 140 may be 0.1 μm or more and 1.5 μm or less.

When the length of the overlapping portion of the plurality of first active holes AH1 and the gate electrode 140 is less than 0.1 μm, the gate electrode 140 and the plurality of first active holes AH1 or the plurality of second active holes AH2 may not overlap each other during the actual process, and thus the first length L_{CHa} of the channel part (refer to 121 of FIG. 1B) may be different by the plurality of first active holes AH1.

In addition, when the length of the overlapping portion of the plurality of first active holes AH1 and the gate electrode 140 exceeds 1.5 μm, the resistance of the active layer 120 may become too large when the thin film transistor substrate according to an embodiment of present disclosure is turned on, resulting in lower charge mobility and lower device characteristics of the thin film transistor substrate.

According to another embodiment of the present disclosure, a length of each of the plurality of first active holes AH1 and the plurality of second active holes AH2 may gradually increase from an edge portion of the active layer 120 to a center portion of the active layer 120. More specifically, as shown in the enlarged view of FIG. 3, the first hole AH1a may have a first length d1, the second hole AH1b may have a second length d2, and the third hole AH1c may have a third length d3. In this case, the first length d1 may be greater than the second length d2, and the second length d2 may be greater than the third length d3.

By forming in this way, even if the conducting process is performed on a partial region of the active layer 120 by using the gate electrode 140 as a mask, a phenomenon in which the length of the channel part in the central portion of the active layer 120 is excessively shortened may be suppressed. Accordingly, in the thin film transistor substrate according to an example embodiment of the present disclosure, the length of the channel part 121 of FIG. 1B in the second direction Y may be the same in the first direction X.

According to another embodiment of the present disclosure, since a portion where each of the plurality of first active holes AH1 overlaps with the gate electrode 140 has the same length, and each of the plurality of first active holes AH1 has different lengths, the curvature of the virtual curve connecting the centers of one ends of the plurality of first active holes AH1 adjacent to the gate electrode 140 may be different from the curvature of the virtual curve connecting the centers of another ends of the plurality of first active holes AH1 adjacent to the source electrode 161, for example, the centers of the left ends. In this case, the curvature of the virtual curve formed by the left ends of the plurality of first active holes AH1 may be smaller than the curvature of the virtual curve formed by the right ends of the plurality of first active holes AH1. Meanwhile, since the plurality of second active holes AH2 are the same as the plurality of first active holes AH1, repeated descriptions thereof will be omitted.

According to another embodiment of the present disclosure, the first side 141a and the second side 141b of the gate electrode 140 are provided in a convex curved shape, and the length of the plurality of first active holes AH1 and the plurality of second active holes AH2 is gradually reduced from the center of the active layer 120 to the edge of the active layer 120 while overlapping the convex gate electrode 140, even if the conducting process for forming the thin film transistor substrate according to another embodiment of the present disclosure is performed, dopant ions or plasma are prevented from excessively diffusing into the channel part, thereby securing the length of the channel part as designed.

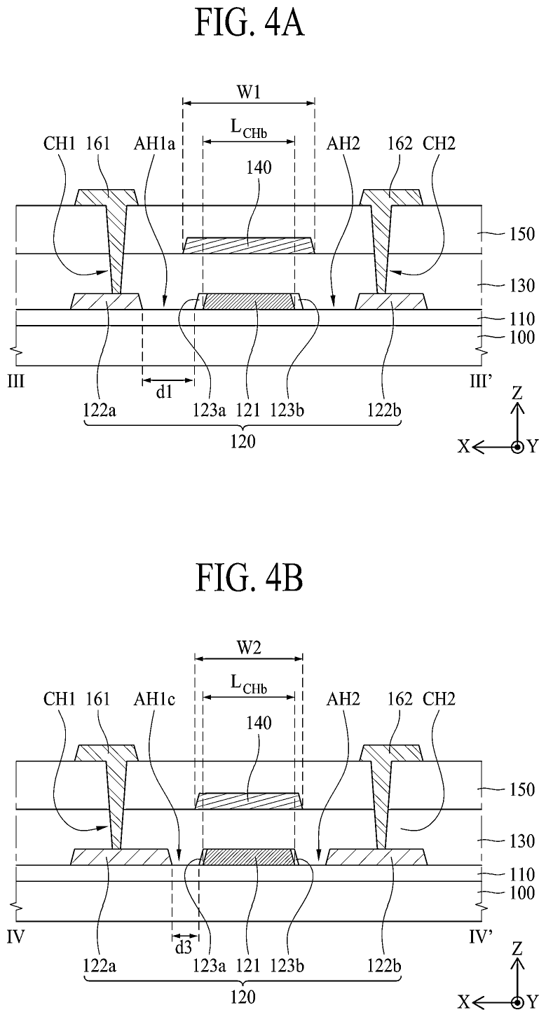

FIG. 4A is a cross-sectional view of a thin film transistor substrate according to an example embodiment of the present disclosure. In this case, the cross-sectional view of FIG. 4A corresponds to the cross-section taken along the line III-III′ of FIG. 3. Meanwhile, an embodiment of FIG. 4A is the same as an embodiment of FIG. 2A except for the configuration of the active hole, and thus different configurations will be mainly described below.

As shown in FIG. 4A, the active layer 120 may include a channel part 121, a first connection part 122a, a second connection part 122b, a first intermediate part 123a, and a second intermediate part 123b. Meanwhile, unlike an embodiment of FIG. 2A, a first hole AH1a of the plurality of first active holes AH1 may be provided on one side of the channel part 121, for example, on the left side, and any one of the plurality of second active holes AH2 may be provided on another side, for example, on the right side, of the channel part 121.

The first hole AH1a of the plurality of first active holes AH1 may overlap one end of the gate electrode 140, for example, a left end. By forming in this way, one end of the first intermediate part 123a, for example, a left end and the one end of the gate electrode 140 may not correspond to each other.

According to another embodiment of the present disclosure, since the gate electrode 140 is provided in a convex shape, and the active layer 120 is provided with the plurality of first active holes AH1 and the plurality of second active holes AH2, the channel part 121 may have a second channel length L_{CHb}.

According to another embodiment of the present disclosure, the first hole AH1a among the plurality of first active holes AH1 may have the first length d1 in the first direction X.

According to another embodiment of the present disclosure, by forming the plurality of first active holes AH1 and the plurality of second active holes AH2, the first intermediate part 123a and the second intermediate part 123b may be located inside the gate electrode 140. For example, unlike in FIG. 2A, one end of the first intermediate part 123a, for example, a right end, corresponds to one end of the channel part 121, for example, a left end, and another end of the first intermediate part 123a, for example, a left end, overlaps the gate electrode 140 and may not correspond to one end of the gate electrode 140, for example, a left end. Likewise, one end of the second intermediate part 123b, for example, a left end, corresponds to another end of the channel part 121, for example, a right end, and another end of the second intermediate part 123b, for example, overlaps the gate electrode 140 and may not correspond to another end of the gate electrode 140, for example, a right end.

By forming in this way, the length of the first intermediate part 123a and the second intermediate part 123b in the first direction X is reduced compared to that of FIG. 2A, and thus the degree of diffusion of dopant ions or plasma into the channel part 121 may be reduced.

FIG. 4B is a cross-sectional view of a thin film transistor substrate according to an example embodiment of the present disclosure. In this case, the cross-sectional view of FIG. 4B corresponds to the cross-section taken along the line IV-IV′ of FIG. 3. Meanwhile, an embodiment of FIG. 4B is the same as an embodiment of FIG. 2B except for the configuration of the active hole, and thus different configurations will be mainly described below.

As shown in FIG. 4B, the active layer 120 may include a channel part 121, a first connection part 122a, a second connection part 122b, a first intermediate part 123a, and a second intermediate part 123b. Meanwhile, unlike an embodiment of FIG. 2B, a third hole AH1c of the plurality of first active holes AH1 may be provided on one side of the channel part 121, for example, on the left side thereof, and any one of the plurality of second active holes AH2 may be provided on another side, for example, on the right side, of the channel part 121.

The third hole AH1c of the plurality of first active holes AH1 may overlap one end of the gate electrode 140, for example, a left end. By forming in this way, one end of the first intermediate part 123a, for example, a left end and the one end of the gate electrode 140 may not correspond to each other.

According to another embodiment of the present disclosure, since the gate electrode 140 is provided in a convex shape, and further, the active layer 120 is provided with the plurality of first active holes AH1 and the plurality of second active holes AH2, the channel part 121 may have a second channel length L_{CHb}. In this case, the second channel length L_{CHb} of the channel part 121 illustrated in FIG. 4B may be the same as the second channel length L_{CH}b of the channel part 121 illustrated in FIG. 4A.

According to another embodiment of the present disclosure, the third hole AH1c among the plurality of first active holes AH1 may have the third length d3 in the first direction X, which may be smaller than the first length d1 of the first hole AH1a among the plurality of first active holes AH1 shown in FIG. 4A.

According to another embodiment of the present disclosure, by forming the plurality of first active holes AH1 and the plurality of second active holes AH2, the first intermediate part 123a and the second intermediate part 123b may be located inside the gate electrode 140. For example, unlike in FIG. 2B, one end of the first intermediate part 123a, for example, a right end, corresponds to one end of the channel part 121, for example, a left end, and another end of the first intermediate part 123a, for example, a left end, overlaps the gate electrode 140 and may not correspond to one end of the gate electrode 140, for example, a left end. Likewise, one end of the second intermediate part 123b, for example, a left end, corresponds to another end of the channel part 121, for example, a right end, and another end of the second intermediate part 123b, for example, overlaps the gate electrode 140 and may not correspond to another end of the gate electrode 140, for example, a right end.

By forming in this way, the length of the first intermediate part 123a and the second intermediate part 123b in the first direction X is reduced compared to that of FIG. 2B, and thus the degree of diffusion of dopant ions or plasma into the channel part 121 may be reduced.

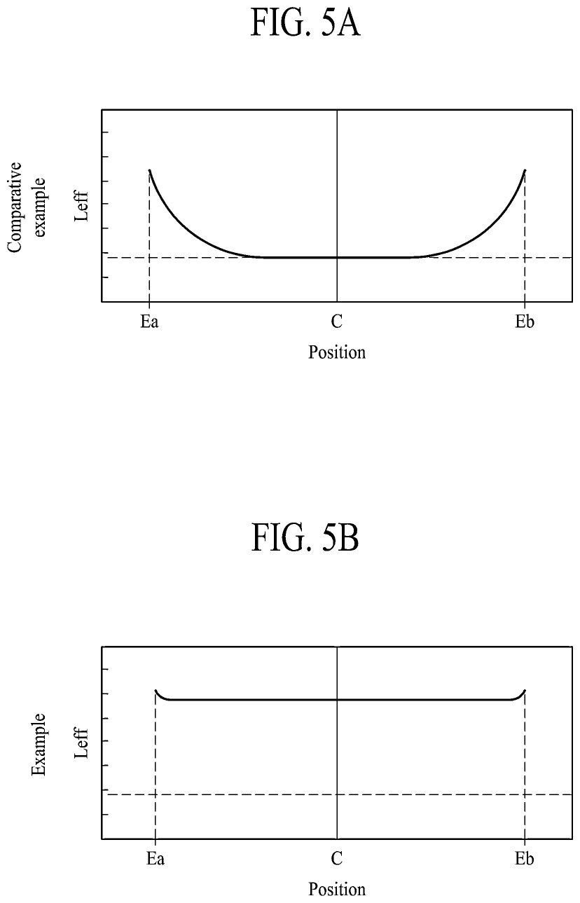

FIG. 5A is a graph showing the length Leff of a channel part according to a position of a thin film transistor substrate according to a comparative example, and FIG. 5B is a graph showing the length Leff of a channel part according to a position of a thin film transistor substrate according to another embodiment of the present disclosure.

First, the thin film transistor substrate according to the comparative example of FIG. 5A corresponds to a case in which a gate electrode does not have a convex first side or a convex second side, and a plurality of active holes are not provided, and the thin film transistor substrate according to the embodiment of FIG. 5B corresponds to a case in which a gate electrode of FIG. 3 includes a convex first side and a second side, and a plurality of first active holes and a plurality of second active holes are provided along the first side and the second side. In this case, the central portion C of the active layer and the edge portions Ea and Eb of the active layer shown in FIG. 5B correspond to the central portion C of the active layer and the edge portions Ea and Eb of the active layer shown in FIG. 3. For example, the length Leff of the channel part at positions Ea and Eb of the active layer of FIG. 5B corresponds to the length of the channel part in the first direction X in the edge portion Ea of the active layer and the edge portion Eb of the active layer of FIG. 3, respectively, and the length Leff of the channel part at the position C of FIG. 5B corresponds to the length of the channel part in the first direction X in the center portion C of the active layer of FIG. 3.

As shown in FIG. 5A, when the convex first side or the convex second side is not provided, the length Leff of the channel part formed in the central portion C of the active layer is smaller than the length Leff of the channel part formed in the edge portions Ea and Eb of the active layer. This is because in the central portion C of the active layer 120, the diffusion rate of dopant ions or plasma in the process of conducting the conducting process on the active layer is faster than the diffusion rate of the dopant ions or plasma in the edge portions Ea and Eb of the active layer 120.

Meanwhile, according to an example embodiment of the present disclosure, the gate electrode 140 includes the convex first side 141a and the convex second side 141b, and includes the plurality of first active holes AH1 overlapping the first side 141a and the plurality of second active holes AH2 overlapping the second side 141b, and thus the length Leff of the channel part 121 formed at the central portion C of the active layer 120 and the length Leff of the channel part 121 formed at the edge portions Ea and Eb of the active layer 120 have almost the same value.

As a result, according to one embodiment of the present disclosure, by the gate electrode 140 including the convex first side 141a and the convex second side 141b, the plurality of first active holes AH1 and the plurality of second active holes AH2 overlapping each of the first side 141a and the second side 141b, respectively, although the diffusion rate of dopant ions or plasma in the central portion C of the active layer 120 is relatively faster than the diffusion rate of dopant ions or plasma in the edge portions Ea and Eb of the active layer 120, the length Leff of the channel part 121 formed in the central portion C of the active layer 120 and the edge portions Ea and Eb of the active layer 120 may be formed to be the same.

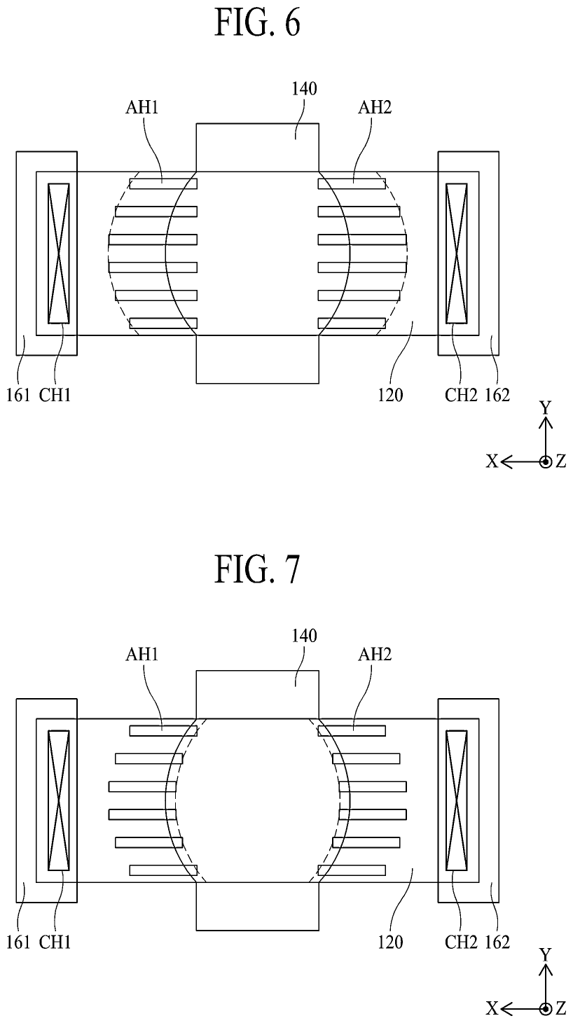

FIG. 6 is a plan view of a thin film transistor substrate according to another embodiment of the present disclosure. Meanwhile, an embodiment according to FIG. 6 is the same as an embodiment according to FIG. 3 except for configurations of a plurality of first active holes and a plurality of second active holes, and thus different configurations will be mainly described below.

As shown in FIG. 6, a thin film transistor substrate according to another embodiment of the present disclosure may include an active layer 120, a gate electrode 140, a source electrode 161, and a drain electrode 162.

According to another configuration of the present disclosure, one end of the plurality of first active holes AH1, for example, each of the right ends overlapping the gate electrode 140 may be connected to form a virtual straight line. One end of the plurality of second active holes AH2, for example, each of the left ends overlapping the gate electrode 140 may be connected to form a virtual straight line.

Another end of the plurality of first active holes AH1, for example, the center of each of the left ends adjacent to the source electrode 161 may form a virtual curve. In this case, the virtual curve formed by connecting the centers of the left ends of the plurality of first active holes AH1 may be the same as the curvature of the first side 141a of FIG. 1A of the gate electrode 140. Likewise, another end of the plurality of second active holes AH2, for example, the center of each of the right ends adjacent to the drain electrode 162 may form a virtual curve. In this case, the virtual curve formed by connecting the centers of the right ends of the plurality of second active holes AH2 may be the same as the curvature of the second side 141b of FIG. 1A of the gate electrode 140.

According to another embodiment of the present disclosure, since the width of the gate electrode 140 decreases from the center of the active layer 120 to the edge of the active layer 120, and the lengths of the plurality of first active holes AH1 and the plurality of second active holes AH2 decrease, when the conducting process is performed on the active layer 120, the degree of diffusion of dopant ions or plasma at the center of the active layer 120 and the degree of diffusion of dopant ions or plasma at the edge of the active layer 120 are reduced, and further, the length of the channel part 121 according to another embodiment of the present disclosure at the central portion and the length of the channel part 121 according to another embodiment of the present disclosure at the edge portion may be formed to be the same.

FIG. 7 is a plan view of a thin film transistor substrate according to another embodiment of the present disclosure. Meanwhile, an embodiment of FIG. 7 is the same as an embodiment of FIG. 3 except for configurations of a plurality of first active holes and a plurality of second active holes, and thus different configurations will be mainly described below.

As shown in FIG. 7, a thin film transistor substrate according to another embodiment of the present disclosure may include an active layer 120, a gate electrode 140, a source electrode 161, and a drain electrode 162.

According to another embodiment of the present disclosure, each of the plurality of first active holes AH1 may be formed to have the same length, and each of the plurality of second active holes AH2 may be formed to have the same length.

According to another embodiment of present disclosure, since each of the plurality of first active holes AH1 is formed with the same length, and one end of each of the plurality of the first active hole AH1, for example, the center of the right end overlapping the gate electrode 140 is connected to form a virtual curve, the degree to which dopant ions or plasma are diffused in the center portion of the active layer 120 is reduced than the degree to which dopant ions or plasma are diffused in the edge portion of the active layer 120, so that the length of the channel part 121 according to another embodiment of the present disclosure at the central portion and the length of the channel part 121 according to another embodiment of the present disclosure at the edge portion may be formed to be the same.

Since each of the plurality of second active holes AH2 is formed to have the same length, and one end of each of the plurality of the second active hole AH2, for example, the center of the left end overlapping the gate electrode 140 is connected to form a virtual curve, the degree to which dopant ions or plasma are diffused in the center portion of the active layer 120 is reduced than the degree to which dopant ions or plasma are diffused in the edge portion of the active layer 120, so that the length of the channel part 121 according to another embodiment of the present disclosure at the central portion and the length of the channel part 121 according to another embodiment of the present disclosure at the edge portion may be formed to be the same.

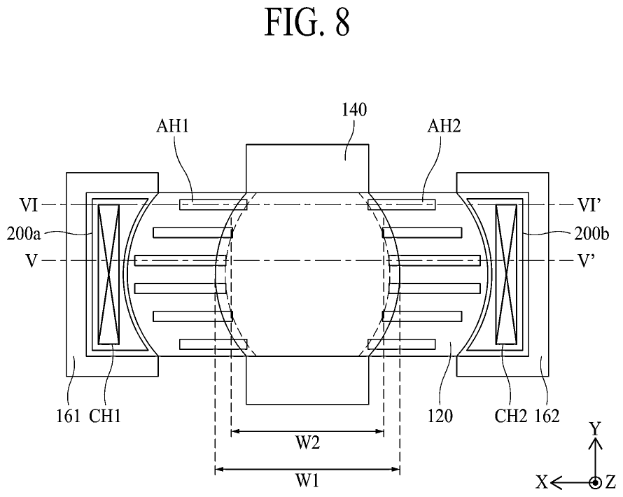

FIG. 8 is a plan view of a thin film transistor substrate according to another embodiment of the present disclosure. Meanwhile, an embodiment according to FIG. 8 is the same as an embodiment according to FIG. 3 except for configurations of a source electrode, a drain electrode, and a conductive material layer, and thus different configurations will be mainly described below.

As shown in FIG. 8, a thin film transistor substrate according to another embodiment of the present disclosure may include an active layer 120, a gate electrode 140, a source electrode 161, a drain electrode 162, a first conductive material layer 200a, and a second conductive material layer 200b.

According to another embodiment of the present disclosure, the source electrode 161 and the drain electrode 162 include a side concavely provided in the direction of the gate electrode 140. By doing in this way, a region to be conductive of the active layer 120 is reduced by the source electrode 161 and the drain electrode 162, and thus the degree of diffusion of dopant ions or plasma in the direction of the channel part 121 in the process of conducting the conducting process on the active layer 120 may be reduced.

The thin film transistor substrate according to another embodiment of the present disclosure further may include a first conductive material layer 200a and a second conductive material layer 200b.

The first conductive material layer 200a may be provided on one side of the active layer 120, for example, on a left side, and the second conductive material layer 200b may be provided on another side, for example, on a right side, of the active layer 120. In this case, the first conductive material layer 200a may overlap one side of the active layer 120 and the source electrode 161, and the second conductive material layer 200b may overlap another side of the active layer 120 and the drain electrode 162.

According to another embodiment of the present disclosure, the first conductive material layer 200a and the second conductive material layer 200b may be provided in the same shape as the source electrode 161 and the drain electrode 162, respectively. Specifically, the first conductive material layer 200a includes a side provided concavely with a certain curvature in the direction of the gate electrode 140 like the source electrode 161, and the second conductive material layer 200b includes a side provided concavely with a certain curvature in the direction of the gate electrode 140, similar to the drain electrode 162.

FIG. 9A is a cross-sectional view of a thin film transistor substrate according to another embodiment of the present disclosure. In this case, the cross-sectional view of FIG. 9A corresponds to the cross-section taken along the line V-V′ of FIG. 8. Meanwhile, an embodiment of FIG. 9A is the same as an embodiment of FIG. 4A except for the configuration of the active layer, the source electrode, the drain electrode, and the conductive material layer, and thus different configurations will be mainly described below.

As shown in FIG. 9A, a thin film transistor substrate according to another embodiment of the present disclosure may include a substrate 100, a buffer layer 110, an active layer 120, a gate insulating layer 130, a gate electrode 140, an interlayer insulating layer 150, a source electrode 161, a drain electrode 162, a first conductive material layer 200a, and a second conductive material layer 200b.

Unlike the embodiment according to FIG. 4A, the source electrode 161 and the drain electrode 162 are provided on the gate insulating layer 130, and may be formed of the same material in the same layer as the gate electrode 140. Furthermore, the source electrode 161 and the drain electrode 162 may be patterned in the same process as the gate electrode 140.

Therefore, a separate contact hole for connecting the active layer 120 with the source electrode 161 or the drain electrode 162 may not be provided in the interlayer insulating layer 150.

In the thin film transistor substrate according to another embodiment of the present disclosure, since the gate electrode 140, the source electrode 161, and the drain electrode 162 are formed on the same layer and in the same process, not only the gate electrode 140 but also the source electrode 161 and the drain electrode 162 are used as masks to impart conductive properties to some areas of the active layer 120.

Specifically, the active layer 120 includes a channel part 121, a first connection part 122a, a second connection part 122b, a first intermediate part 123a, and a second intermediate part 123b. In this case, since the channel part 121, the first intermediate part 123a, and the second intermediate part 123b are the same as those of FIG. 4A described above, repeated descriptions thereof will be omitted.

According to another embodiment of the present disclosure, the first connection part 122a includes a first region 122al that does not overlap the source electrode 161 and a second region 122a2 that overlaps the source electrode 161. In this case, the first region 122al is not covered by the source electrode 161 and thus may have conductive characteristics by dopant ions or plasma while the conducting process is performed, and since the second region 122a2 is covered by the source electrode 161, a separate conductive characteristic may not be provided while the conducting process is performed.

Likewise, the second connection part 122b includes a first region 122b1 that does not overlap the drain electrode 162 and a second region 122b2 that overlaps the drain electrode 162. In this case, the first region 122b1 is not covered by the drain electrode 162, and thus may have conductive characteristics by dopant ions or plasma while the conducting process is performed, and the second region 122b2 may not have separate conductive characteristics during the conducting process.

The first conductive material layer 200a may be provided on the first connection part 122a. Specifically, the first conductive material layer 200a may be provided to be in contact with the upper surface of the second region 122a2 of the first connection part 122a. Likewise, the second conductive material layer 200b may be provided on the second connection part 122b. Specifically, the second conductive material layer 200b may be provided to be in contact with the upper surface of the second region 122b2 of the second connection part 122b. By forming as described above, the active layer 120 and the source electrode 161 may be electrically connected to each other by the first conductive material layer 200a, and the active layer 120 and the drain electrode 162 may be electrically connected to each other by the second conductive material layer 200b.

The source electrode 161 or the drain electrode 162 may have a first length L1 in the first direction X. In connection with FIG. 8, since the source electrode 161 or the drain electrode 162 of the thin film transistor substrate according to another embodiment of the present disclosure has a concave side toward the gate electrode 140, the first length L1 of the source electrode 161 or the drain electrode 162 provided in the intermediate region of the active layer 120 may be formed to be shorter than the second length (see L2 of FIG. 9B) of the source electrode 161 or the drain electrode 162 provided at an edge portion of the active layer 120.

FIG. 9B is a cross-sectional view of a thin film transistor substrate according to another embodiment of the present disclosure. In this case, the cross-sectional view of FIG. 9B corresponds to the cross-section taken along the line VI-VI′ of FIG. 8. Meanwhile, an embodiment of FIG. 9B is the same as an embodiment of FIG. 9A except for the configuration of the active layer, the gate electrode, the source electrode, the drain electrode, the first conductive material layer, and the second conductive material layer, and thus different configurations will be mainly described below.

As shown in FIG. 9B, the first connection part 122a and the second connection part 122b of the active layer 120 may be formed to be longer than the first connection part 122a and the second connection part 122b of the thin film transistor substrate according to the embodiment of FIG. 9A.

In connection with FIG. 8, since the source electrode 161 or the drain electrode 162 of the thin film transistor substrate according to another embodiment of the present disclosure has a concave side toward the gate electrode 140, the second length L2 of the source electrode 161 or the drain electrode 162 provided in the edge portion of the active layer 120 may be formed to be longer than the first length (see L1 of FIG. 9A) of the source electrode 161 or the drain electrode 162 provided in the central portion of the active layer 120 described above.

By forming in this way, the area to be conductive of the active layer 120 by the source electrode 161 and the drain electrode 162 is reduced, so that the degree of diffusion of dopant ions or plasma in the process of conducting the conducting process on the active layer 120 may be reduced.

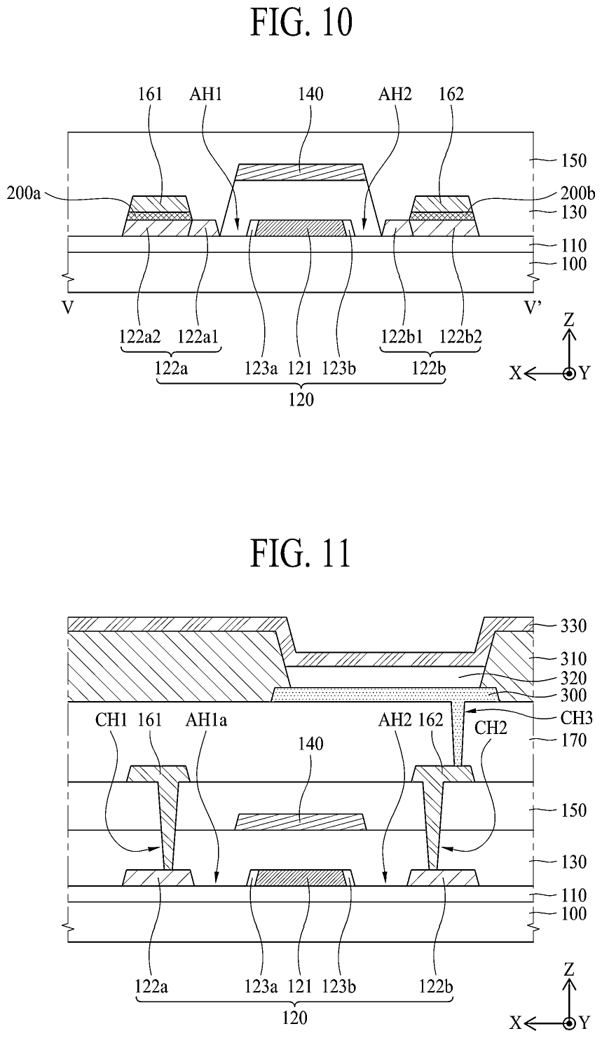

FIG. 10 is a cross-sectional view of a thin film transistor substrate according to another embodiment of the present disclosure. In this case, the cross-sectional view of FIG. 10 corresponds to the cross-section taken along the line V-V′ of FIG. 8. Meanwhile, an embodiment of FIG. 10 is the same as an embodiment of FIG. 9A except for the configuration of the gate insulating layer, and thus different configurations will be mainly described below.

As shown in FIG. 10, the thin film transistor substrate according to another embodiment of the present disclosure may be formed in an etch structure in which a partial region of the gate insulating layer 130 is etched.

Specifically, the etch structure refers to a structure in which one end and another end of the gate insulating layer 130 are formed to coincide with one end and another end of the gate electrode 140 by dry etching a partial area of the gate insulating layer 130 with the gate electrode 140 as a mask.

In this case, the gate insulating layer 130 may be formed on the substrate 100 to correspond to the gate electrode 140, not on the entire surface of the substrate 100.

Unlike the embodiment according to FIG. 9A, the source electrode 161 and the drain electrode 162 may be provided to directly contact upper surfaces of the first conductive material layer 200a and the second conductive material layer 200b. Specifically, the source electrode 161 may be provided to contact upper surfaces of the first conductive material layer 200a, and the drain electrode 162 may be provided to contact upper surfaces of the second conductive material layer 200b.

According to another embodiment of the present disclosure, a portion of the gate insulating layer 130 may be provided inside the plurality of first active holes AH1 and the plurality of second active holes AH2, and a portion of the interlayer insulating layer 150 may be provided inside the plurality of first active holes AH1 and the plurality of second active holes AH2.

FIG. 11 is a cross-sectional view of a display device including a thin film transistor substrate according to an example embodiment of the present disclosure.

As shown in FIG. 11, a display device according to an example embodiment of the present disclosure includes a substrate 100, a buffer layer 110, an active layer 120, a gate insulating layer 130, a gate electrode 140, an interlayer insulating layer 150, a source electrode 161, a drain electrode 162, a planarization layer 170, a first electrode 300, a bank layer 310, a light emitting layer 320, and a second electrode 330.

Since the substrate 100, the buffer layer 110, the active layer 120, the gate insulating layer 130, the gate electrode 140, the interlayer insulating layer 150, the source electrode 161, and the drain electrode 162 are the same as those in the above-described embodiments, only different configurations will be described below.

A planarization layer 170 may be provided on the source electrode 161 and the drain electrode 162.

A third contact hole CH3 may be provided in the planarization layer 170 so that the source electrode 161 may be exposed by the third contact hole CH3. However, in some cases, the drain electrode 162 may be exposed by the third contact hole CH3.

The first electrode 300 may be formed on the planarization layer 170 and may be connected to the source electrode 161 or the drain electrode 162 through the contact hole. The first electrode 300 may function as an anode.

The bank layer 310 may be provided to cover an edge of the first electrode 300 to define a light emitting area. Accordingly, an upper surface area of the first electrode 300 exposed without being covered by the bank layer 310 becomes a light emitting area.

The light emitting layer 320 may be provided on the first electrode 300. The light emitting layer 320 may include red, green, and blue light emitting layers patterned for each pixel, or may include a white light emitting layer connected from all pixels. When the light emitting layer 320 is formed of a white light emitting layer, the light emitting layer 320 may include, for example, a first stack including a blue light emitting layer, a second stack including a yellow-green light emitting layer, and a charge generation layer provided between the first stack and the second stack, but is not limited thereto.

The second electrode 330 may be provided on the light emitting layer 320. The second electrode 330 may function as a cathode.

Although not shown, an encapsulation layer for preventing moisture or oxygen from penetrating may be additionally formed on the second electrode 330.

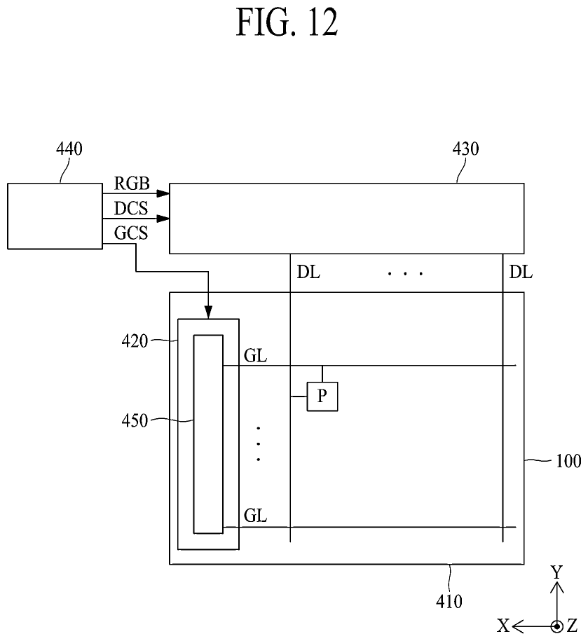

FIG. 12 is a schematic view of a display device according to an example embodiment of the present disclosure.

As shown in FIG. 12, the display device according to an example embodiment of the present disclosure may include a display panel 410, a gate driver 420, a data driver 430, and a controller 440.

The display panel 410 includes gate lines GLs and data lines DLs, and pixels P are disposed in respective crossing areas of the gate lines GLs and data lines DLs. An image is displayed by driving the pixel P. The gate lines GLs, the data lines DLs, and the pixels P may be disposed on the substrate 100.

The controller 440 controls the gate driver 420 and the data driver 430. The controller 440 outputs a gate control signal GCS for controlling the gate driver 420 and a data control signal DCS for controlling the data driver 430 by using a signal supplied from an external system (not shown). Also, the controller 440 samples input video data input from the external system and rearranges the sampled input video data, and supplies the rearranged digital video data RGB to the data driver 430.

The gate control signal GCS includes a gate start pulse GSP, a gate shift clock GSC, a gate output enable signal GOE, a start signal Vst, and a gate clock GCLK. Further, control signals for controlling a shift register may be included in the gate control signal GCS.

The data control signal DCS includes a source start pulse SSP, a source shift clock signal SSC, a source output enable signal SOE, and a polarity control signal POL.

The data driver 430 supplies a data voltage to the data lines DL of the display panel 410. Specifically, the data driver 430 converts the video data RGB inputted from the controller 440 into an analog data voltage and supplies the data voltage to the data lines DL.

The gate driver 420 may be mounted on the display panel 410. As described above, a structure in which the gate driver 420 is directly mounted on the display panel 410 is referred to as a gate in panel (GIP) structure. Specifically, in the gate-in-panel (GIP) structure, the gate driver 420 may be disposed on the substrate 100.

The gate driver 420 may include a shift register 450.

The shift register 450 sequentially supplies gate pulses to the gate lines GL during one frame by the use of start signal and gate clock transmitted from the controller 440. Herein, the one frame refers to a period in which one image is outputted through the display panel 410. The gate pulse has a turn-on voltage capable of turning on a switching device (thin film transistor) disposed in the pixel P.

Also, during the remaining period of one frame, in which the gate pulse is not supplied, the shift register 450 supplies a gate-off signal capable of turning off the switching device to the gate line GL. Hereinafter, the gate pulse and the gate-off signal are totally referred to as a scan signal GS.

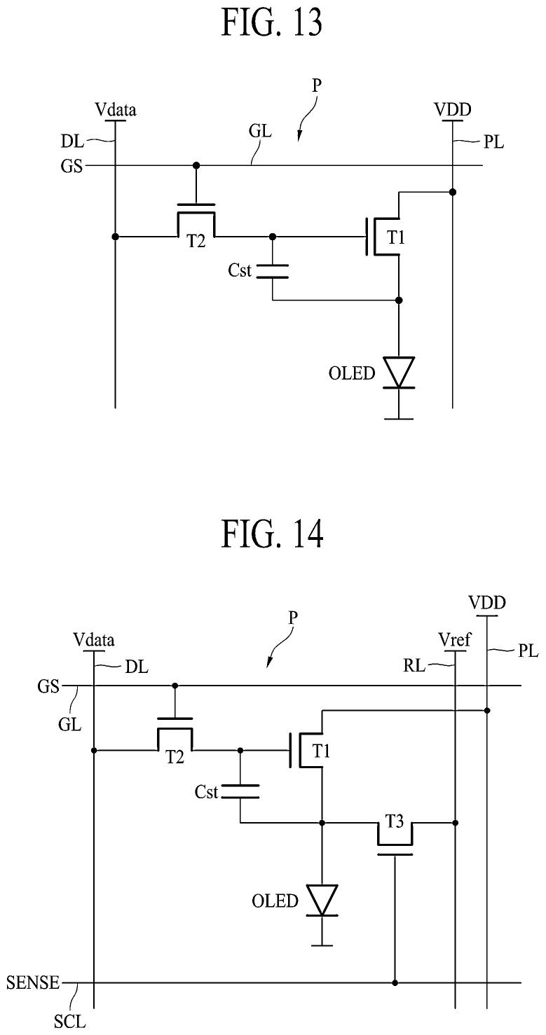

FIG. 13 is a circuit diagram of a pixel included in a display device according to an example embodiment of the present disclosure.

As shown in FIG. 13, the display device according to an embodiment of present disclosure includes first to second thin film transistors T1 and T2 and capacitors Cst.

The first thin film transistor T1 is a driving thin film transistor, and the second thin film transistor T2 is a switching thin film transistor. At least one of the first thin film transistor T1 and the second thin film transistor T2 may be formed of the above-described various thin film transistors.

The first thin film transistor T1 is switched according to the data voltage Vdata supplied from the second thin film transistor T2, generates a data current from the driving voltage VDD supplied from the power line PL, and supplies it to the organic light emitting diode OLED.

The second thin film transistor T2 is switched according to the gate signal GS supplied to the gate line GL and supplies the data voltage Vdata supplied from the data line DL to the first thin film transistor T1.

According to an example embodiment of the present disclosure, the thin film transistor according to an embodiment of FIGS. 1A to 10 described above may be used as any one of the first thin film transistor T1 and the second thin film transistor T2.

The capacitor Cst serves to maintain the data voltage supplied to the first thin film transistor T1 for one frame, and is provided between the gate electrode and the source electrode of the first thin film transistor T1.

The organic light emitting diode OLED emits predetermined light according to a data current supplied from the first thin film transistor T1.

FIG. 14 is a circuit diagram of a pixel included in a display device according to another embodiment of the present disclosure.

As shown in FIG. 14, the display device according to another embodiment of present disclosure includes first to third thin film transistors T1, T2, T3 and a capacitor Cst.

The first thin film transistor T1 is a driving thin film transistor, and the second to third thin film transistors T2 to T3 are switching thin film transistors.

The first thin film transistor T1 is switched according to the data voltage Vdata supplied from the second thin film transistor T2, generates a data current from the driving voltage VDD supplied from the power line PL, and supplies it to the organic light emitting diode OLED.

The second thin film transistor T2 is switched according to the gate signal GS supplied to the gate line GL and supplies the data voltage Vdata supplied from the data line DL to the first thin film transistor T1.

The third thin film transistor T3 supplies the current of the first thin film transistor T1 to the reference line RL in response to the sensing control signal SENSE supplied from the scan line SCL. A reference voltage Vref is supplied to the reference line RL.

According to an example embodiment of the present disclosure, the thin film transistor according to an embodiment of FIGS. 1A to 10 described above may be used as any one of the first thin film transistor T1 to the third thin film transistor T3.

The capacitor Cst serves to maintain the data voltage supplied to the first thin film transistor T1 for one frame, and is provided between the gate electrode and the source electrode of the first thin film transistor T1.

The organic light emitting diode OLED emits predetermined light according to a data current supplied from the first thin film transistor T1.

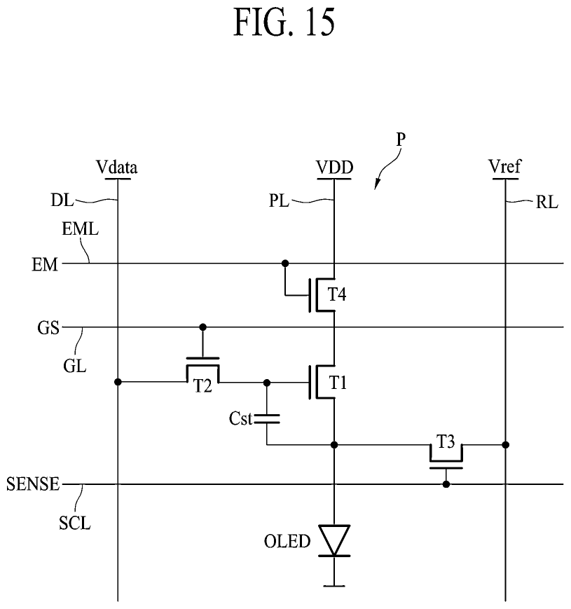

FIG. 15 is a circuit diagram of a pixel included in a display device according to another embodiment of the present disclosure.

As shown in FIG. 15, the display device according to another embodiment of the present disclosure includes first to fourth thin film transistors T1, T2, T3, and T4 and a capacitor Cst.

The first thin film transistor T1 is a driving thin film transistor, and the second to fourth thin film transistors T2 to T4 are switching thin film transistors.

The first thin film transistor T1 is switched according to the data voltage Vdata supplied from the second thin film transistor T2, generates a data current from the driving voltage VDD supplied from the power line PL, and supplies it to the organic light emitting diode OLED.

The second thin film transistor T2 is switched according to the gate signal GS supplied to the gate line GL and supplies the data voltage Vdata supplied from the data line DL to the first thin film transistor T1.

The third thin film transistor T3 supplies the current of the first thin film transistor T1 to the reference line RL in response to the sensing control signal SENSE supplied from the scan line SCL. A reference voltage Vref is supplied to the reference line RL.

The fourth thin film transistor T4 is switched according to the light emission control signal EM supplied to the light emission control line EML and supplies the driving voltage VDD supplied from the power line PL to the first thin film transistor T1.

According to an example embodiment of the present disclosure, the thin film transistor according to an embodiment of FIGS. 1A to 10 described above may be used as any one of the first thin film transistor T1 to the fourth thin film transistor T4.

The capacitor Cst serves to maintain the data voltage supplied to the first thin film transistor T1 for one frame, and is provided between the gate electrode and the source electrode of the first thin film transistor T1.

The organic light emitting diode OLED emits predetermined light according to a data current supplied from the first thin film transistor T1.

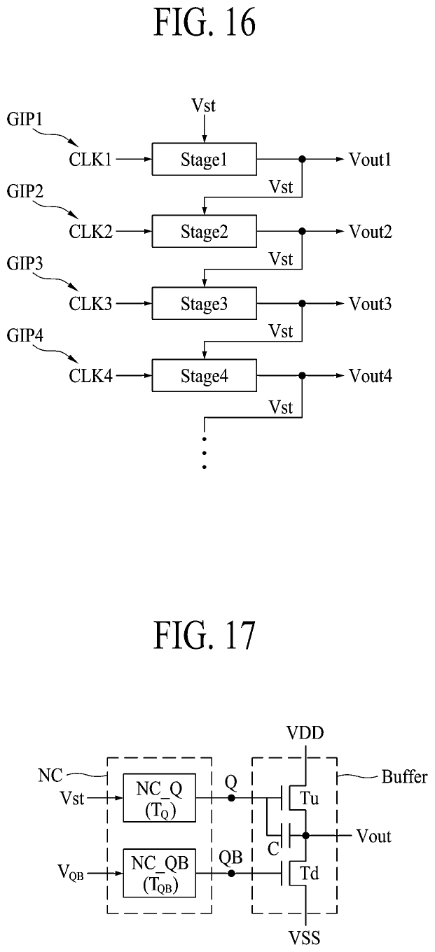

FIG. 16 is a schematic diagram of a shift register according to an example embodiment of the present disclosure.

As shown in FIG. 16, each of the plurality of GIP circuits GIP1, GIP2, GIP3 and GIP4 outputs the gate signal Vout1, Vout2, Vout3 and Vout4 for one frame and supplies it to the gate wiring.

Specifically, the first stage Stage 1 of the first GIP circuit GIP1 is initiated by a separate start signal Vst, outputs the first gate signal Vout1 using the first clock signal CLK1 and supplies to the first gate wiring.

The second to fourth stage Stage 2˜Stage 4 of each of the second to fourth GIP circuits GIP2, GIP3 and GIP4 is initiated by the signal Vst, outputs the second to fourth gate signals Vout2, Vout3 and Vout4 using the second to fourth clock signal CLK2, CLK3 and CLK4 and supplies to the second to fourth gate wiring.

On the other hand, though it is not illustrated, when the last gate signal Vout is output at the stage of the last GIP circuit where one frame ends, the stage of the last GIP circuit is initialized by receiving the reset signal Vreset, and then the first gate signal Vout1 is output at the first stage stage 1 of the first GIP circuit GIP1 where the next frame starts and above described is repeated.

FIG. 17 is a circuit diagram of a shift register according to an example embodiment of the present disclosure.

As shown in FIG. 17, the GIP circuit includes a pull-up node Q, a pull-down node QB, a node controller NC, and a buffer unit Buffer.

The buffer unit Buffer is connected to an output terminal and includes a pull-up transistor Tu, a pull-down transistor Td, and a capacitor C.

The pull-up transistor Tu is turned on to output the gate-on signal when the pull-up node Q is charged with a gate high voltage.

The pull-down transistor Td is turned on to output the gate-off signal when the pull-down node QB is charged with a gate low voltage.

The capacitor C serves to maintain the gate high voltage supplied to the pull-up transistor Tu for one frame, and is provided between the gate terminal and the source terminal of the pull-up transistor Tu.

The node controller NC controls charging and discharging between the pull-up node Q and the pull-down node QB. The node controller NC may include a pull-up node controller NC_Q for controlling charging and discharging of the pull-up node Q and a pull-down node controller NC_QB for controlling charging and discharging of the pull-down node QB. The pull-up node controller NC_Q includes at least one transistor T_{Q} for controlling the pull-up node Q, and the pull-down node controller NC_QB includes at least one transistor T_{QB} for controlling the pull-down node QB.

The output of the gate signal Vout may be stably controlled by the node controller NC. Specifically, the node controller NC discharges the pull-down node QB to a gate low voltage when the pull-up node Q is charged with a gate high voltage, and discharges the pull-up node Q to a gate low voltage when the pull-down node QB is charged with a gate high voltage.

Therefore, when the start signal Vst is applied, the pull-up node Q is charged with a gate high voltage and the pull-down node QB is discharged with a gate low voltage by the operation of the plurality of transistors T_{Q} and T_{QB} provided in the node controller NC, thereby outputting the high power supply voltage VDD as the gate signal Vout. In addition, when a discharge signal V_{QB} is applied, the pull-up node Q is charged with a gate low voltage and the pull-down node QB is charged with a gate high voltage by the operation of the plurality of transistors T_{Q} and T_{QB} provided in the node controller NC to output a low power voltage VSS as a gate signal Vout.

According to an example embodiment of the present disclosure, the thin film transistor according to an embodiment of FIGS. 1A to 10 described above may be used as any one of the pull-up transistor Tu, the pull-down transistor Td, and a plurality of transistors T_{Q} and T_{QB} provided in the node controller NC. Accordingly, the present disclosure may have the following advantages.

According to one embodiment of present disclosure, the gate electrode is provided in a convex shape and the width of the gate electrode increases from the edge of the active layer to the center of the active layer. Even if the conducting process is carried out to conduct a partial area of the active layer with the gate electrode as a mask, the degree of diffusion of dopant ions or plasma in the center of the active layer is controlled so that the length of the channel part in the center portion of the active layer and the length of the channel part in the edge portion of the active layer are the same.

According to an example embodiment of the present disclosure, a plurality of active holes may be provided along the side of a gate electrode provided in a convex shape, and the plurality of active holes may be gradually lengthened from the edge of the active layer to the center of the active layer.

According to an example embodiment of the present disclosure, a gate electrode having a convex shape and a plurality of active holes formed along the convex sides of the gate electrode may be formed to have the same length of the channel part at the center portion of the active layer and the edge portion of the active layer, thereby implementing device characteristics as designed.

According to an example embodiment of the present disclosure, when the source electrode and the drain electrode include a side having a certain curvature like a gate electrode, and thus a conducting process to give conductive properties to a partial area of the active layer using the source electrode, the drain electrode, and the gate electrode as a mask, the area in which the active layer is conductive may be reduced by the curved shape of the source electrode and the drain electrode, and the total amount of dopant or plasma diffused inside the active layer may be reduced, thereby eliminating or minimizing an excessive decrease in the length of the channel part in the center portion of the active layer.

It will be apparent to those skilled in the art that various substitutions, modifications, and variations are possible within the scope of the present disclosure without departing from the spirit and scope of the present disclosure. Therefore, the scope of the present disclosure is represented by the following claims, and all changes or modifications derived from the meaning, range and equivalent concept of the claims should be interpreted as being included in the scope of the present disclosure.

What is claimed is:

1. A thin film transistor substrate, comprising:
a substrate;
an active layer disposed on the substrate;
a gate electrode disposed on the active layer;
a source electrode connected to one side of the active layer; and
a drain electrode connected to another side of the active layer,
wherein the gate electrode includes a first side convexly disposed in a direction of any one of the source electrode and the drain electrode,
wherein the active layer includes a plurality of first active holes overlapping the first side, and
wherein the plurality of first active holes are arranged in a direction perpendicular to a direction in which the source electrode and the drain electrode face each other.

2. The thin film transistor substrate according to claim 1,
wherein the first side convexly disposed in the direction of any one of the source electrode and the drain electrode is disposed as an arc having a certain curvature.

3. The thin film transistor substrate according to claim 1,
wherein the active layer includes a channel part, a first connection part disposed on one side of the channel part, and a first intermediate part disposed between the channel part and the first connection part,
wherein the first connection part does not overlap the gate electrode,
wherein the first intermediate part overlaps the gate electrode, and
wherein an end side of the first intermediate part is convexly disposed to correspond to the first side of the gate electrode.

4. The thin film transistor substrate according to claim 1,
wherein the active layer includes a channel part, a first connection part disposed on one side of the channel part, and a first intermediate part disposed between the channel part and the first connection part,
wherein the first connection part does not overlap the gate electrode,
wherein the first intermediate part is disposed inside the gate electrode, and
wherein an end side of the first intermediate part does not correspond to the first side of the gate electrode.

5. The thin film transistor substrate according to claim 1,
wherein a length of any one of the plurality of first active holes closest to an upper side of the active layer is shorter than a length of another of the plurality of first active holes closest to a center of the active layer.

6. The thin film transistor substrate according to claim 1,
wherein yet another first active hole of the plurality of first active holes is disposed between any one of the plurality of first active holes closest to an upper side of the active layer and another one of the plurality of first active holes closest to a center of the active layer, and
wherein a length of the yet another first active hole is longer than a length of the any one of the plurality of first active holes and shorter than a length of the another of the plurality of first active holes.

7. The thin film transistor substrate according to claim 5,
wherein a length of a portion where the any one of the plurality of first active holes overlaps the gate electrode and a length of a portion where the another one of the plurality of first active holes overlaps the gate electrode are same as each other.

8. The thin film transistor substrate according to claim 1,
wherein a length of a portion where each of the plurality of first active holes overlaps the gate electrode is equal to or more than 0.1 μm and equal or less than 1.5 μm.

9. The thin film transistor substrate according to claim 1,
wherein one ends of the plurality of first active holes are disposed with a predetermined curvature along the first side of the gate electrode.

10. The thin film transistor substrate according to claim 9,
wherein a curvature formed by the one ends of the plurality of first active holes is smaller than a curvature formed by another ends of the plurality of first active holes,
wherein the one end of each of the plurality of first active holes is disposed to be adjacent to any one of the source electrode and the drain electrode, and
wherein the another end of each of the plurality of first active holes is disposed to be adjacent to the gate electrode.

11. The thin film transistor substrate according to claim 9,
wherein another ends of the plurality of first active holes form a virtual straight line,
wherein the one end of each of the plurality of first active holes is disposed to be adjacent to any one of the source electrode and the drain electrode, and
wherein the another end of each of the plurality of first active holes is disposed to be adjacent to the gate electrode.

12. The thin film transistor substrate according to claim 9,
wherein each of the plurality of first active holes has a same length.

13. The thin film transistor substrate according to claim 1,
wherein any one of the source electrode and the drain electrode includes a second side concavely disposed in the direction of the gate electrode.

14. The thin film transistor substrate according to claim 13,
wherein the second side concave in the direction of the gate electrode is disposed as an arc having a certain curvature.

15. The thin film transistor substrate according to claim 13, further comprising:
a first conductive material layer disposed on the active layer,
wherein the first conductive material layer includes a third side concavely disposed in the direction of the gate electrode.

16. The thin film transistor substrate according to claim 1,
wherein the gate electrode includes a fourth side convexly disposed in a direction of another one of the source electrode and the drain electrode.

17. The thin film transistor substrate according to claim 16,
wherein the active layer further includes a plurality of second active holes overlapping the fourth side, and
wherein the plurality of second active holes are arranged in a direction perpendicular to a direction in which the source electrode and the drain electrode face each other.

18. The thin film transistor substrate according to claim 17,
wherein each of the plurality of second active holes has a different length, and
wherein a length of any one of the plurality of second active holes closest to an upper side of the active layer is shorter than a length of another one of the plurality of second active holes closest to a center of the active layer.

19. The thin film transistor substrate according to claim 17,
wherein one ends of the plurality of second active holes are disposed with a predetermined curvature along the fourth side of the gate electrode.

20. A display device including a thin film transistor substrate comprising:
a substrate;
an active layer disposed on the substrate;
a gate electrode disposed on the active layer;
a source electrode connected to one side of the active layer; and
a drain electrode connected to another side of the active layer,
wherein the gate electrode includes a first side convexly disposed in a direction of any one of the source electrode and the drain electrode,
wherein the active layer includes a plurality of first active holes overlapping the first side, and
wherein the plurality of first active holes are arranged in a direction perpendicular to a direction in which the source electrode and the drain electrode face each other.
